(19) United States
(12) Patent Application Publication
(10) Pub. No.: US 2024/0429351 A1
(43) Pub. Date: Dec. 26, 2024

(54) DISPLAY DEVICE

(71) Applicant: Samsung Display Co., LTD., Yongin-si (KR)

(72) Inventors: Yong Seok CHOI, Yongin-si (KR); Song Yi KIM, Yongin-si (KR); Su Jin KIM, Yongin-si (KR); Ki Heon LEE, Yongin-si (KR)

(73) Assignee: Samsung Display Co., LTD., Yongin-si (KR)

(21) Appl. No.: 18/598,506

(22) Filed: Mar. 7, 2024

(30) Foreign Application Priority Data
Jun. 21, 2023 (KR) 10-2023-0079700

(51) Int. Cl. H01L 33/50; H01L 33/32

(52) U.S. Cl. CPC H01L 33/502; H01L 33/32; H01L 33/505

(57) ABSTRACT

A display device includes a color conversion layer disposed above a light emitting element and including a first quantum dot and a second quantum dot. A core of the first quantum dot includes a Group I-III-VI semiconductor compound, and a core of the second quantum dot includes a Group III-V semiconductor compound.

### CROSS-REFERENCE TO RELATED APPLICATION(S)

This application claims priority to and benefits of Korean patent application No. 10-2023-0079700 under 35 U.S.C. § 119(a), filed on Jun. 21, 2023, in the Korean Intellectual Property Office (KIPO), the entire contents of which are incorporated herein by reference.

### BACKGROUND

### 1. Technical Field

The disclosure generally relates to a display device.

### 2. Description of the Related Art

Recently, as interest in information displays is increased, research and development of display devices have been continuously conducted.

### SUMMARY

Embodiments provide a display device having an improved efficiency of a color conversion layer.

In accordance with an embodiment of the disclosure, a display device may include a color conversion layer disposed above a light emitting element and including a first quantum dot and a second quantum dot. A core of the first quantum dot may include a Group I-III-VI semiconductor compound, and a core of the second quantum dot may include a Group III-V semiconductor compound.

The Group I-III-VI semiconductor compound may include AgInS, AgInS₂, CuInS, CuInS₂, CuGaO₂, CuInGaS, AgGaO₂, AgInGaS, or a combination thereof.

The Group III-V semiconductor compound may include InP, InAs, GaP, GaAs, GaN, AlP, AlAs, AlN, or a combination thereof.

A content of the second quantum dot may be greater than a content of the first quantum dot.

The color conversion layer may include a first layer and a second layer.

The first layer may include the first quantum dot, and the second layer may include the second quantum dot.

A thickness of the second layer may be greater than a thickness of the first layer.

The color conversion layer may further include a light scattering particle.

The light emitting element may include a first electrode, a second electrode, and a light emitting layer between the first electrode and the second electrode.

The display device may further include a color filter layer on the color conversion layer.

In accordance with an embodiment of the disclosure, a display device may include a first color conversion layer and a second color conversion layer, disposed above a light emitting element. The first color conversion layer may include a first quantum dot and a second quantum dot, the second color conversion layer may include a third quantum dot, a core of the first quantum dot may include a Group I-II-VI semiconductor compound, and a core of the second quantum dot and a core of the third quantum dot may include a Group III-V semiconductor compound.

The Group I-III-VI semiconductor compound may include AgInS, AgInS₂, CuInS, CuInS₂, CuGaO₂, CuInGaS, AgGaO₂, AgInGaS, or a combination thereof.

The Group III-V semiconductor compound may include InP, InAs, GaP, GaAs, GaN, AlP, AlAs, AlN, or a combination thereof.

A content of the second quantum dot may be greater than a content of the first quantum dot.

The first color conversion layer may include a first layer and a second layer.

The first layer may include the first quantum dot, and the second layer may include the second quantum dot.

A thickness of the second layer may be greater than a thickness of the first layer.

A thickness of the second color conversion layer may be greater than a thickness of the second layer.

The first color conversion layer and the second color conversion layer may further include a light scattering particle.

The light emitting element may include a first electrode, a second electrode, and a light emitting layer between the first electrode and the second electrode.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic cross-sectional view of a display device in accordance with an embodiment of the disclosure.

FIG. 2 is a schematic cross-sectional view of a display device in accordance with an embodiment of the disclosure.

FIGS. 3 to 7 are schematic cross-sectional views illustrating process steps of a method of manufacturing a display device in accordance with an embodiment of the disclosure.

FIGS. 8 to 10 are schematic cross-sectional views illustrating process steps of a method of manufacturing a display device in accordance with an embodiment of the disclosure.

### DETAILED DESCRIPTION OF THE EMBODIMENTS

The effects and characteristics of the disclosure and a method of achieving the effects and characteristics will be clear by referring to the embodiments described below in detail together with the accompanying drawings. However, the disclosure is not limited to the embodiments disclosed herein but may be implemented in various forms. The embodiments are provided by way of example only so that a person of ordinary skilled in the art can fully understand the features in the disclosure and the scope thereof. Therefore, the disclosure can be defined by the scope of the appended claims.

The terminology used herein is for the purpose of describing particular embodiments only and is not construed as limiting the disclosure. The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly. Like reference numerals generally denote like elements throughout the specification.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

It will be understood that, although the terms “first,” “second,” etc. may be used herein to describe various elements, these elements should not be limited by these terms. These terms are only used to distinguish one element from another element. Thus, a “first” element discussed below could also be termed a “second” element without departing from the teachings of the disclosure.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described in more detail with reference to the accompanying drawings.

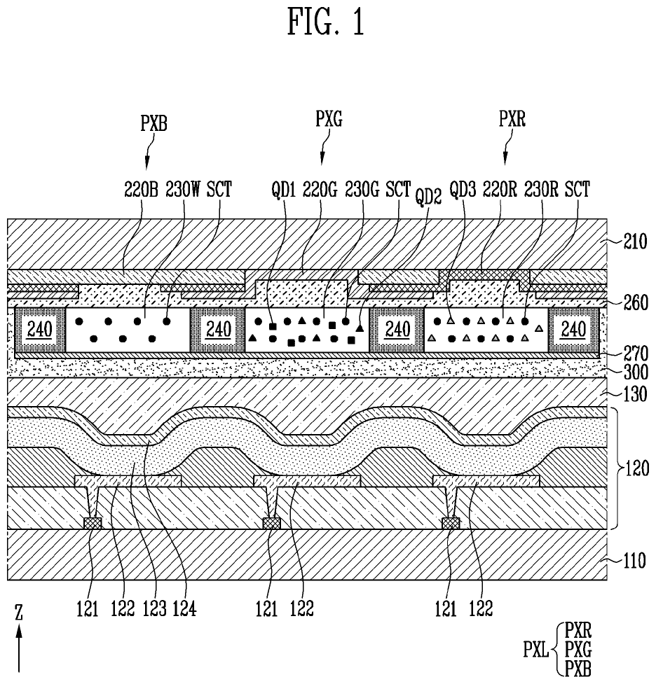

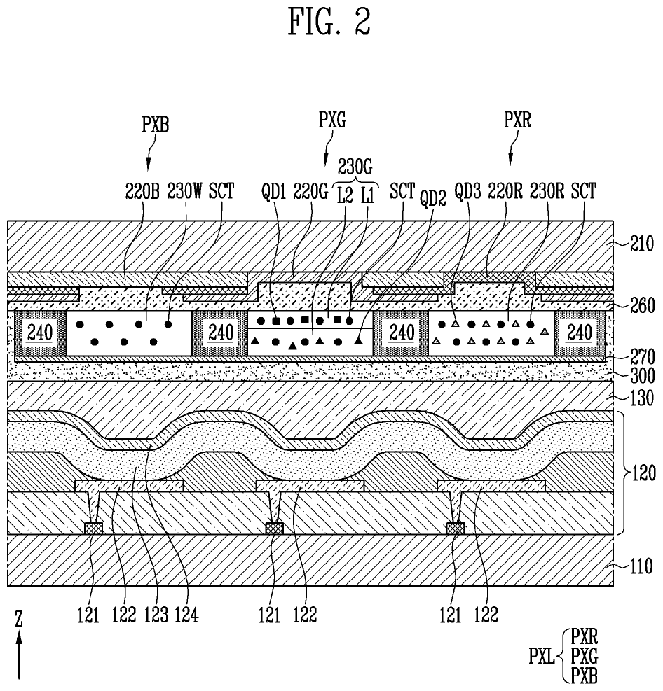

FIGS. 1 and 2 are schematic cross-sectional views of a display device in accordance with an embodiment of the disclosure.

Referring to FIGS. 1 and 2, a pixel PXL may include a first pixel PXG, a second pixel PXR, and/or a third pixel PXB. Hereinafter, when at least one of the first pixel PXG, the second pixel PXR, and the third pixel PXB is arbitrarily designated or when two or more kinds of the first pixel PXG, the second pixel PXR, and the third pixel PXB are inclusively designated, each of the first, second, and third pixels PXG, PXR, and PXB or the first, second, and third pixels PXG, PXR, and PXB will be referred to as a “pixel PXL” or “pixels PXL.”

The first pixel PXG may emit light of a first color, the second pixel PXR may emit light of a second color, and the third pixel PXB may emit light of a third color. The first pixel PXG may be a green pixel emitting light of green, the second pixel PXR may be a red pixel emitting light of red, and the third pixel PXB may be a blue pixel emitting light of blue. However, the disclosure is not limited thereto. At least one first pixel PXG, at least one second pixel PXR, and at least one third pixel PXB, which are disposed adjacent to each other, may constitute one pixel unit capable of emitting lights of various colors.

In an embodiment, the first pixel PXG, the second pixel PXR, and the third pixel PXB may have light emitting elements 120 emitting light of the same color, and include color conversion layers of different colors and/or color filters of different colors, which are disposed above the respective light emitting elements 120, to respectively emit lights of the first color, the second color, and the third color. In another embodiment, the first pixel PXG, the second pixel PXR, and the third pixel PXB may have, as light sources, a light emitting element of the first color, a light emitting element of the second color, and a light emitting element of the third color, to emit lights of the first color, the second color, and the third color, respectively. However, the color, kind, and/or number of each pixel PXL are not particularly limited. For example, the color of light emitted by each pixel PXL may be variously changed.

The display device may be formed in a structure in which a first substrate 110 on which the light emitting elements 120 are disposed and a second substrate 210 on which color conversion layers 230G, 230R, 230W and/or a color filter layer 220G, 220R, and 220B are disposed are bonded together with a filling material 300 interposed between the first substrate 110 and the second substrate 210. However, the disclosure is not necessarily limited thereto. In embodiments, the color conversion layers 230G, 230R, 230W and/or the color filter layer 220G, 220R, and 220B may be stacked on (e.g., directly on) the light emitting elements 120.

The first substrate 110 may constitute a base member, and may be a rigid or flexible substrate or film. For example, the first substrate 110 may be a rigid substrate made of glass or tempered glass, a flexible substrate (or thin film) made of a plastic or a metal, or at least one insulating layer. The material and/or property of the first substrate 110 are/is not particularly limited.

A pixel circuit 121 may be disposed on the first substrate 110. The pixel circuit 121 may include at least one thin film transistor, at least one capacitor, various signal lines, and the like. The pixel circuit 121 may be electrically connected to a first electrode 122 of the light emitting element 120.

The light emitting element 120 may be disposed above the pixel circuit 121. The light emitting element 120 may include the first electrode 122, a second electrode 124, and a light emitting layer 123 between the first electrode 122 and the second electrode 124. The light emitting element 120 may generate light, using a principle that holes and electrons injected from the first electrode 122 and the second electrode 124 are recombined in the light emitting layer 123, thereby emitting light. In an embodiment, the light emitting layer 123 may generate light having a wavelength in a range of about 430 nm to about 500 nm, and the light emitted from the light emitting layer 123 may be converted into lights of the first color, the second color, and the third color in the respective color conversion layer 230G, 230R, and 230W.

The second electrode 124 may be disposed on the light emitting layer 123. The second electrode 124 may be configured with a metal layer including silver (Ag), magnesium (Mg), aluminum (Al), platinum (Pt), palladium (Pd), gold (Au), nickel (Ni), neodymium (Nd), iridium (Ir), chromium (Cr) or any alloy thereof, and/or a transparent conductive layer including indium tin oxide (ITO), indium zinc oxide (IZO), zinc oxide (ZnO) or indium tin zinc oxide (ITZO). In embodiments, the second electrode 124 may be configured as a multi-layer including at least two layers including a metal thin layer. For example, the second electrode 124 may be configured as a triple layer of ITO/Ag/ITO.

A thin film encapsulation layer 130 may be disposed over the light emitting elements 120. The thin film encapsulation layer 130 may have a single-layer structure or a multi-layer structure. The thin film encapsulation layer 130 may include multiple insulating layers covering the light emitting elements 120. The thin film encapsulation layer 130 may include at least one inorganic layer and at least one organic layer. For example, the thin film encapsulation layer 130 may have a structure in which the inorganic layer and the organic layer are alternately stacked with each other.

The filling material 300 may be disposed on the thin film encapsulation layer 130. The filling material 300 may be interposed between the first substrate 110 and the second substrate 210 to perform a function of bonding the first substrate 110 and the second substrate 210 together and maintaining a proper distance between the first substrate 110 and the second substrate 210. Thus, the filling material 300 may be applied between the first substrate 110 and the second substrate 210, and the first substrate 110 and the second substrate 210 may be bonded together, so that the filling material 200 may serve to firmly combining the first substrate 110 and the second substrate 210 together while properly maintaining a distance between the first substrate 110 and the second substrate 210.

A bank 240 and the color conversion layers 230G, 230R, and 230W may be disposed on the filling material 300. The bank 240 may be disposed between the first to third pixels PXG, PXR, and PXB or at boundaries of the first to third pixels PXG, PXR, and PXB, and include openings respectively overlapping the first to third pixels PXG, PXR, and PXB in a plan view. The openings of the bank 240 may provide spaces in which the color conversion layers 230G, 230R, and 230W can be provided.

The color conversion layers 230G, 230R, and 230W may be disposed on the light emitting elements 120 in the openings of the bank 240. The color conversion layers 230G, 230R, and 230W may include a first color conversion layer 230G disposed in the first pixel PXG, a second color conversion layer 230R disposed in the second pixel PXR, and a light scattering layer 230W disposed in the third pixel PXB.

The first color conversion layer 230G may include a first quantum dot QD1 and a second quantum dot QD2, which convert light emitted from the light emitting element 120 into light of the first color. For example, the first quantum dot QD1 and the second quantum dot QD2 of the first color conversion layer 230G may be dispersed in a matrix material such as a base resin.

In an embodiment, in case that the light emitting element 120 is a blue light emitting element emitting light of blue, and the first pixel PXG is a green pixel, the first color conversion layer 230G may include the first quantum dot QD1 and the second quantum dot QD2, which convert light of blue, which is emitted from the blue light emitting element, into light of green. The first quantum dot QD1 and the second quantum dot QD2 may absorb blue light and emit green light by shifting a wavelength of the blue light according to energy transition. In case that the first pixel PXG is a pixel of another color, the first color conversion layer 230G may include the first quantum dot QD1 and the second quantum dot QD2, which correspond to the color of the first pixel PXG.

Each of the first quantum dot QD1 and the second quantum dot QD2 may have a core-shell structure including a core including a semiconductor compound and a shell including an oxide of a metal, a metalloid, or a non-metal, a semiconductor compound, or any combination thereof. For example, the material included in the core and the material included in the shell may be different from each other. The shell of each of the first quantum dot QD1 and the second quantum dot QD2 may serve as a protective layer for maintaining semiconductor characteristics by preventing a chemical modification of the core and/or a charging layer for providing electrophoresis characteristics. The shell may be a single layer or a multi-layer.

The core of the first quantum dot QD1 may include a Group I-III-VI semiconductor compound. The Group I-III-VI semiconductor compound may include AgInS, AgInS₂, CuInS, CuInS₂, CuGaO₂, CuInGaS, AgGaO₂, AgInGaS, or a combination thereof. The shell of the first quantum dot QD1 may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or a combination thereof.

The core of the second quantum dot QD2 may include a Group III-V semiconductor compound. The Group III-V semiconductor compound may include InP, InAs, GaP, GaAs, GaN, AlP, AlAs, AlN, or a combination thereof. The shell of the second quantum dot QD2 may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or a combination thereof.

In an embodiment, each of the first quantum dot QD1 and the second quantum dot QD2 may be provided in the form of a nano-particle, a nanotube, a nanowire, a nanofiber, a planar nano-particle, or the like, which has a spherical shape, a pyramid shape, a multi-arm shape, or a cubic shape. However, the disclosure is not necessarily limited thereto.

In an embodiment, the first color conversion layer 230G may be formed as a single layer as shown in FIG. 1. In case that the first color conversion layer 230G is formed as a single layer, the first quantum dot QD1 and the second quantum dot QD2 may be provided in the same layer mixed together. In an embodiment, a content of the first quantum dot QD1 of the first color conversion layer 230G and a content of the second quantum dot QD2 of the first color conversion layer 230G may be different from each other. For example, the content of the second quantum dot QD2 may be greater than the content of the first quantum dot QD1, but the disclosure is not necessarily limited thereto.

In embodiments, the first color conversion layer 230G may be formed as a multi-layer. For example, the first color conversion layer 230G may include a first layer L1 and a second layer L2 as shown in FIG. 2. Although a structure in which the first layer L1 is disposed on the second layer L2 is illustrated in FIG. 2, the disclosure is not limited thereto, and a stacked order of the first layer L1 and the second layer L2 may be variously changed. In case that the first color conversion layer 230G is formed as a multi-layer, the first quantum dot QD1 and the second quantum dot QD22 may be separately provided in different layers. For example, the first layer L1 may include the first quantum dot QD1, and the second layer L2 may include the second quantum dot QD2. In an embodiment, thicknesses of the first layer L1 and the second layer L2 may vary according to the contents of the first quantum dot QD1 and the second quantum dot QD2. For example, a thickness of the first layer L1 and a thickness of the second layer L2 may be different from each other. The thickness of the second layer L2 may be greater than the thickness of the first layer L1, but the disclosure is not necessarily limited thereto.

As described above, in case that the Group I-III-VI first quantum dot QD1 and the Group III-V second quantum dot QD2 are applied while being mixed together, efficiency may be improved and reflectivity may be decreased, compared to the case that a Group III-V quantum dot is independently applied. Material cost may be saved and wavelength conversion efficiency may be improved, compared to the case that a Group I-III-VI quantum dot is independently applied.

In embodiments, the first color conversion layer 230G may further include a least one kind of light scattering particle SCT so as to efficiently use light emitted from the light emitting element 120. For example, the light scattering particle SCT may include at least one of barium sulfate (BaSO₄), calcium carbonate (CaCO₃), titanium oxide (TiO₂), silicon oxide (SiO₂), silicon nitride (Si₃N₄), aluminum oxide (Al₂O₃), zirconium oxide (ZrO₂), and zinc oxide (ZnO).

The second color conversion layer 230R may include a third quantum dot QD3 which converts light emitted from the light emitting element 120 into light of the second color. For example, the third quantum dot QD3 of the second color conversion layer 230R may be dispersed in a matrix material such as a base resin.

In an embodiment, in case that the light emitting element 120 is a blue light emitting element emitting light of blue, and the second pixel PXR is a red pixel, the second color conversion layer 230R may include the third quantum dot QD3 which converts light of blue, which is emitted from the blue light emitting element, into light of red. The third quantum dot QD3 may absorb blue light and emit red light by shifting a wavelength of the blue light according to energy transition. In case that the second pixel PXR is a pixel of another color, the second color conversion layer 230R may include the third quantum dot QD3 which corresponds to the color of the second pixel PXR.

The third quantum dot QD3 may have a core-shell structure including a core including a semiconductor compound and a shell including an oxide of a metal, a metalloid, or a non-metal, a semiconductor compound, or any combination thereof. For example, the material included in the core and the material included in the shell may be different from each other. The shell of the third quantum dot QD3 may serve as a protective layer for maintaining semiconductor characteristics by preventing a chemical modification of the core and/or a charging layer for providing electrophoresis characteristics. The shell may be a single layer or a multi-layer.

The core of the third quantum dot QD3 may include a Group III-V semiconductor compound. The Group III-V semiconductor compound may include InP, InAs, GaP, GaAs, GaN, AlP, AlAs, AlN, or a combination thereof. The shell of the third quantum dot QD3 may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or a combination thereof. The third quantum dot QD3 and the second quantum dot QD2 may include a same material, but a core size of the third quantum dot QD3 and a core size of the second quantum dot QD2 may be different from each other.

In an embodiment, the third quantum dot QD3 may be provided in the form of a nano-particle, a nanotube, a nanowire, a nanofiber, a planar nano-particle, or the like, which has a spherical shape, a pyramid shape, a multi-arm shape, or a cubic shape. However, the disclosure is not necessarily limited thereto.

In embodiments, the second color conversion layer 230R may further include a least one kind of light scattering particle SCT so as to efficiently use light emitted from the light emitting element 120. For example, the light scattering particle SCT may include at least one of barium sulfate (BaSO₄), calcium carbonate (CaCO₃), titanium oxide (TiO₂), silicon oxide (SiO₂), silicon nitride (Si₃N₄), aluminum oxide (Al₂O₃), zirconium oxide (ZrO₂), and zinc oxide (ZnO).

In an embodiment, light of blue having a relatively short wavelength in a visible light band may be incident into the quantum dots QD1, QD2, and QD3 of the first and second color conversion layers 230G and 230R, so that absorption coefficients of the quantum dots QD1, QD2, and QD3 may be increased. Accordingly, the efficiency of light finally emitted from the first pixel PXG and the second pixel PXR may be improved, and excellent color reproduction may be ensured. The first to third pixels PXG, PXR, and PXB may be configured by using light emitting elements 120 of the same color (e.g., blue light emitting elements), so that the manufacturing efficiency of the display device can be improved.

The light scattering layer 230W may be provided to efficiently use light emitted from the light emitting element 120. For example, in case that the light emitting element 120 is a blue light emitting element emitting light of blue, and the third pixel PXB is a blue pixel, the light scattering layer 230W may include at least one kind of light scattering particle SCT to efficiently use light emitted from the light emitting element 120. For example, the light scattering particle SCT of the light scattering layer 230W may include at least one of barium sulfate (BaSO₄), calcium carbonate (CaCO₃), titanium oxide (TiO₂), silicon oxide (SiO₂), silicon nitride (Si₃N₄), aluminum oxide (Al₂O₃), zirconium oxide (ZrO₂), and zinc oxide (ZnO). In embodiments, the light scattering particle SCT may be omitted, and the light scattering layer 230W configured with transparent polymer may be provided.

In an embodiment, a capping layer 270 may be disposed between the color conversion layers 230G, 230R, and 230W and the filling material 300. The capping layer 270 may be provided throughout the first to third pixels PXG, PXR, and PXB. The capping layer 270 may cover the color conversion layers 230G, 230R, and 230W. The capping layer 270 may prevent the color conversion layers 230G, 230R, and 230W from being damaged or contaminated due to infiltration of an impurity such as moisture or air from the outside. The capping layer 270 may include an inorganic insulating material, such as silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ). In an embodiment, the capping layer 270 may be formed with a thickness in a range of about 1000 Å to about 10000 Å, but the disclosure is not necessarily limited thereto.

An optical layer 260 may be disposed between the bank 240 and the color conversion layers 230G, 230R, and 230W. The optical layer 260 may function to improve light extraction efficiency by recycling light provided from the color conversion layers 230G, 230R, and 230W through total reflection. To this end, the optical layer 260 may have a refractive index relatively lower than a refractive index of the color conversion layers 230G, 230R, and 230W. For example, the refractive index of the color conversion layers 230G, 230R, and 230W may be in a range of about 1.6 to about 2.0, and the refractive index of the optical layer 260 may be in a range of about 1.1 to about 1.3.

The color filter layer 220G, 220R, and 220B may be disposed on the optical layer 260. The color filter layer 220G, 220R, and 220B may include first to third color filters 220G, 220R, and 220B which accord with colors of the respective pixels PXL. The first to third color filters 220G, 220R, and 220B which accord with colors of the respective first to third pixels PXG, PXR, and PXB may be disposed, so that a full-color image can be displayed.

The color filter layer 220G, 220R, and 220B may include the first color filter 220G disposed in the first pixel PXG to allow light emitted from the first pixel PXG to be selectively transmitted therethrough, the second color filter 220R disposed in the second pixel PXR to allow light emitted from the second pixel PXR to be selectively transmitted therethrough, and a third color filter 220B disposed in the third pixel PXB to allow light emitted from the third pixel PXB to be selectively transmitted therethrough.

In an embodiment, the first color filter 220G, the second color filter 220R, and the third color filter 220B may be respectively a green color filter, a red color filter, and a blue color filter, but the disclosure is not necessarily limited thereto.

The first color filter 220G may overlap the first color conversion layer 230G in a thickness direction (Z-axis direction). The first color filter 220G may include a color filter material for allowing light of the first color (or green) to be selectively transmitted therethrough. For example, in case that the first pixel PXG is a green pixel, the first color filter 220G may include a green color filter material.

The second color filter 220R may overlap the second color conversion layer 230R in the thickness direction (Z-axis direction). The second color filter 220R may include a color filter material for allowing light of the second color (or red) to be selectively transmitted therethrough. For example, in case that the second pixel PXR is a red pixel, the second color filter 220R may include a red color filter material.

The third color filter 220B may overlap the light scattering layer 230W in the thickness direction (Z-axis direction). The third color filter 220BR may include a color filter material for allowing light of the third color (or blue) to be selectively transmitted therethrough. For example, in case that the third pixel PXB is a blue pixel, the third color filter 220B may include a blue color filter material.

In embodiments, the first to third color filters 220G, 220R, and 220B may overlap with each other between the first to third pixels PXG, PXR, and PXB in the thickness direction (Z-axis direction). As such, in case that the first to third color filters 220G, 220R, and 220B are formed to overlap with each other between the first to third pixels PXG, PXR, and PXB, a color mixture defect viewed at the front or side of the display device may be prevented.

The second substrate 210 may be disposed on the color filter layer 220G, 220R, and 220B. The second substrate 210 may protect the display device from external impact, and provide an input surface and/or a display surface to a user. The second substrate 210 may have a multi-layer structure including a glass substrate, a plastic film, a plastic substrate, or a combination thereof. The multi-layer structure may be formed through a continuous process or an adhesion process using an adhesive layer. The whole or a portion of the second substrate 210 may have flexibility.

A method of manufacturing the display device in accordance with an embodiment will be described.

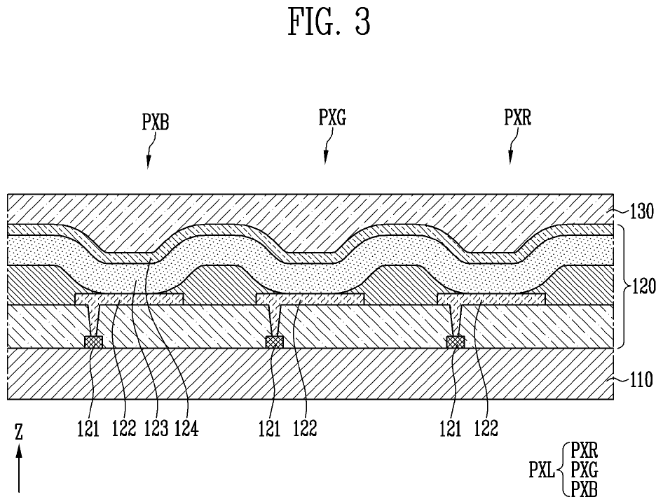

FIGS. 3 to 7 are schematic cross-sectional views illustrating process steps of a method of manufacturing a display device in accordance with an embodiment of the disclosure. Hereinafter, components substantially identical to those shown in FIG. 1 are denoted by the same reference numerals, and overlapping description is omitted.

Referring to FIG. 3, light emitting elements 120 may be formed on a first substrate 110, and a thin film encapsulation layer 130 may be formed over the light emitting elements 120. A first electrode 122 may be formed to overlap each of pixels PXG, PXR, and PXB in the thickness direction (Z-axis direction). A light emitting layer 123 may further include a hole transport area adjacent to the first electrode 122 and an electron transport area adjacent to the second electrode 124. In embodiments, the light emitting layer 123 may further include multiple light emitting units sequentially stacked between the first electrode 122 and the second electrode 124 and a charge generation layer disposed between the light emitting units. As such, in case that the light emitting layer 123 includes the light emitting units and the charge generation layer, the light emitting element 120 may be a tandem light emitting element. In an embodiment, the light emitting layer 123 may be a blue light emitting layer emitting light having a wavelength in a range of about 430 nm to about 500 nm, but the disclosure is not necessarily limited thereto.

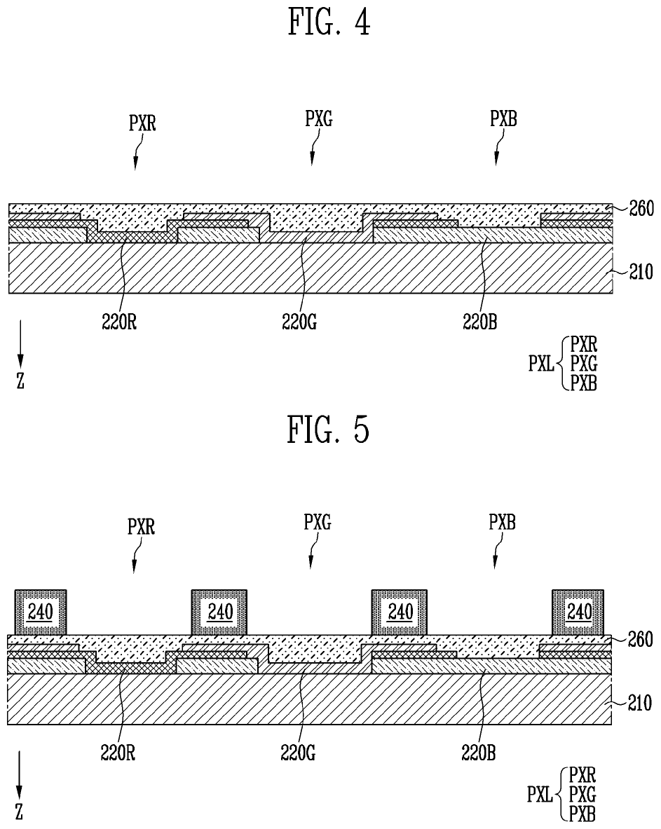

Referring to FIG. 4, a color filter layer 220G, 220R, and 220B may be formed on the second substrate 210, and an optical layer 260 may be formed on the color filter layer 220G, 220R, and 220B. In embodiments, first to third color filters 220G, 220R, and 220B may be formed to overlap with each other between first to third pixels PXG, PXR, and PXB in the thickness direction (Z-axis direction). As such in case that the first to third color filters 220G, 220R, and 220B overlap with each other between first to third pixels PXG, PXR, and PXB, a color mixture defect viewed at the front or side of the display device may be prevented.

The optical layer 260 may be formed throughout the first to third pixels PXG, PXR, and PXB. The optical layer 260 may planarize a step difference due to the color filter layer 220G, 220R, and 220B, but the disclosure is not necessarily limited thereto.

Referring to FIG. 5, a bank 240 may be formed on the optical layer 260. The bank 240 may be disposed between the first to third pixels PXG, PXR, and PXB or at boundaries of the first to third pixels PXG, PXR, and PXB, and include openings respectively overlapping the first to third pixels PXG, PXR, and PXB in the thickness direction (Z-axis direction). The openings of the bank 240 may provide spaces in which color conversion layers 230G, 230R, and 230W can be provided.

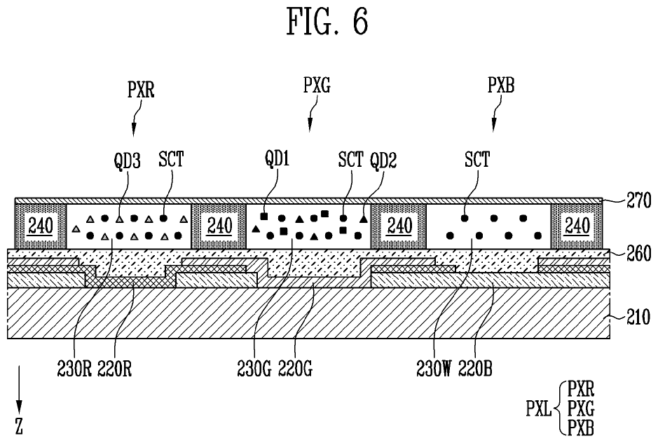

Referring to FIG. 6, the color conversion layers 230G, 230R, and 230W may be formed in the openings of the bank 240, and a capping layer 270 may be formed over the color conversion layers 230G, 230R, and 230W.

A first color conversion layer 230G may be formed in the first pixel PXG, a second color conversion layer 230R may be formed in the second pixel PXR, and a light scattering layer 230W may be formed in the third pixel PXB.

The first color conversion layer 230G may be formed by inkjet-printing a first ink composition including a first quantum dot QD1 and a second quantum dot QD2. For example, the first ink composition may include a monomer, the first quantum dot QD1, the second quantum dot QD2, a light scattering particle SCT, an initiator, a dispersant, and/or a viscosity control agent. A content of the first quantum dot QD1 of the first ink composition and a content of the second quantum dot QD2 of the first ink composition may be different from each other. For example, the content of the second quantum dot QD2 may be greater than the content of the first quantum dot QD1, but the disclosure is not necessarily limited thereto.

A core of the first quantum dot QD1 may include a Group I-III-VI semiconductor compound. The Group I-III-VI semiconductor compound may include AgInS, AgInS₂, CuInS, CuInS₂, CuGaO₂, CuInGaS, AgGaO₂, AgInGaS, or a combination thereof. A shell of the first quantum dot QD1 may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or a combination thereof.

A core of the second quantum dot QD2 may include a Group III-V semiconductor compound. The Group III-V semiconductor compound may include InP, InAs, GaP, GaAs, GaN, AlP, AlAs, AlN, or a combination thereof. A shell of the second quantum dot QD2 may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or a combination thereof.

In an embodiment, each of the first quantum dot QD1 and the second quantum dot QD2 may be provided in the form of a nano-particle, a nanotube, a nanowire, a nanofiber, a planar nano-particle, or the like, which has a spherical shape, a pyramid shape, a multi-arm shape, or a cubic shape. However, the disclosure is not necessarily limited thereto.

As described above, in case that the Group I-III-VI first quantum dot QD1 and the Group III-V second quantum dot QD2 are applied while being mixed together, efficiency may be improved and reflectivity may be decreased, compared to the case that a Group III-V quantum dot is independently applied. Material cost may be saved and wavelength conversion efficiency may be improved, compared to the case that a Group I-III-VI quantum dot is independently applied, which has been described above.

The second color conversion layer 230R may be formed by inkjet-printing a second ink composition including a third quantum dot QD3. For example, the second ink composition may include a monomer, the third quantum dot QD3, a light scattering particle SCT, an initiator, a dispersant, and/or a viscosity control agent.

The core of the third quantum dot QD3 may include a Group III-V semiconductor compound. The Group III-V semiconductor compound may include InP, InAs, GaP, GaAs, GaN, AlP, AlAs, AlN, or a combination thereof. The shell of the third quantum dot QD3 may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or a combination thereof. The third quantum dot QD3 and the second quantum dot QD2 may include a same material, but a core size of the third quantum dot QD3 and a core size of the second quantum dot QD2 may be different from each other.

In an embodiment, the third quantum dot QD3 may be provided in the form of a nano-particle, a nanotube, a nanowire, a nanofiber, a planar nano-particle, or the like, which has a spherical shape, a pyramid shape, a multi-arm shape, or a cubic shape. However, the disclosure is not necessarily limited thereto.

In an embodiment, light of blue having a relatively short wavelength in a visible light band may be incident into the quantum dots QD1, QD2, and QD3 of the first and second color conversion layers 230G and 230R, so that absorption coefficients of the quantum dots QD1, QD2, and QD3 can be increased. Accordingly, the efficiency of light finally emitted from the first pixel PXG and the second pixel PXR may be improved, and excellent color reproduction may be ensured. The first to third pixels PXG, PXR, and PXB may be configured by using light emitting elements 120 of the same color (e.g., blue light emitting elements), so that the manufacturing efficiency of the display device can be improved, which has been described above.

The light scattering layer 230W may be formed by inkjet-printing a third ink composition including a light scattering particle. The light scattering particle SCT may include at least one of barium sulfate (BaSO₄), calcium carbonate (CaCO₃), titanium oxide (TiO₂), silicon oxide (SiO₂), silicon nitride (Si₃N₄), aluminum oxide (Al₂O₃), zirconium oxide (ZrO₂), and zinc oxide (ZnO). The color conversion layers 230G, 230R, and 230W may be cured by irradiating ultraviolet light (UV) onto the printed first to third ink compositions.

Subsequently, the capping layer 270 may be formed over the color conversion layers 230G, 230R, and 230W. The capping layer 270 may be provided throughout the first to third pixels PXG, PXR, and PXB. The capping layer 270 may cover the color conversion layers 230G, 230R, and 230W. The capping layer 270 may prevent the color conversion layers 230G, 230R, and 230W from being damaged or contaminated due to infiltration of an impurity such as moisture or air from the outside. The capping layer 270 may include an inorganic insulating material, such as silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

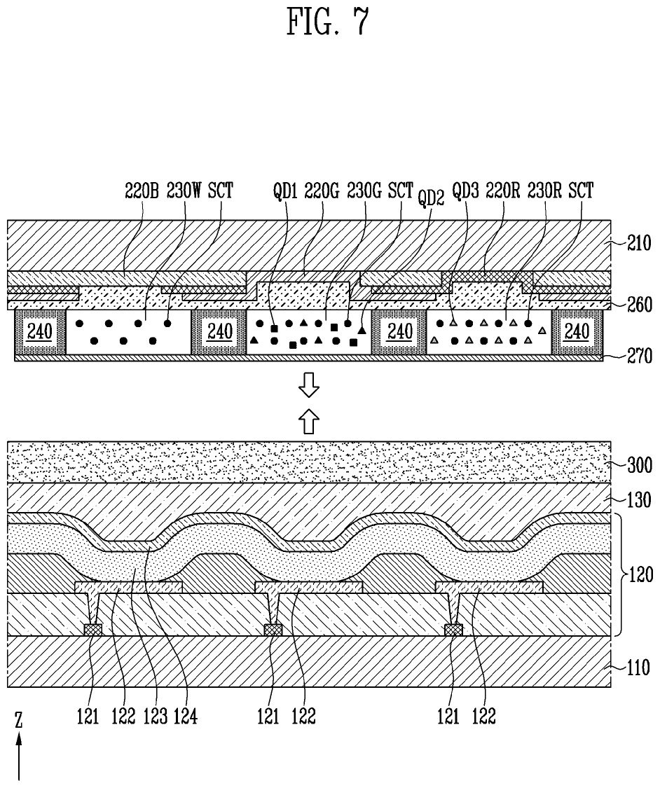

Referring to FIG. 7, subsequently, the first substrate 110 and the second substrate 210 may be bonded together, thereby completing the display device. A filling material 300 may be provided between the first substrate 110 and the second substrate 210. The filling material 300 may be interposed between the thin film encapsulation layer 130 on the first substrate 110 and the capping layer 270 on the second substrate 210 to perform a function of bonding the first substrate 110 and the second substrate 210 together and maintaining a proper distance between the first substrate 110 and the second substrate 210.

Hereinafter, another embodiment will be described. In the following embodiment, components identical to those which have already been described are denoted by the same reference numerals, and overlapping descriptions will be omitted or simplified.

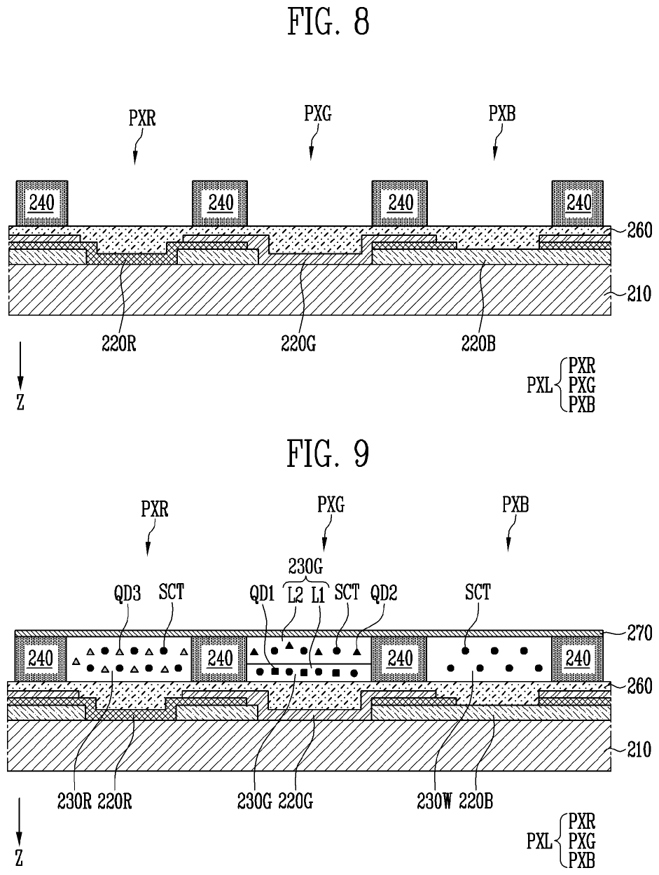

FIGS. 8 to 10 are schematic cross-sectional views illustrating process steps of a method of manufacturing a display device in accordance with an embodiment of the disclosure. Hereinafter, components substantially identical to those shown in FIG. 2 are denoted by the same reference numerals, and overlapping description is omitted.

Referring to FIG. 8, a color filter layer 220G, 220R, and 220B and an optical layer 260 may be formed on the second substrate 210, and a bank 240 may be formed on the optical layer 260. Processes of forming the color filter layer 220G, 220R, and 220B, the optical layer 260, and the bank 240 have been described with reference to FIGS. 3 to 5, and therefore, overlapping descriptions will be omitted.

Referring to FIG. 9, color conversion layers 230G, 230R, and 230W may be formed in openings of the bank 240, and a capping layer 270 may be formed over the color conversion layers 230G, 230R, and 230W.

A first color conversion layer 230G may be formed in a first pixel PXG, a second color conversion layer 230R may be formed in a second pixel PXR, and a light scattering layer 230W may be formed in a third pixel PXB.

The first color conversion layer 230G may be formed by sequentially inkjet-printing a first composition including a first quantum dot QD1 and a second composition including a second quantum dot QD2 and curing the printed first and second compositions. Accordingly, the first color conversion layer 230G may be formed as a multi-layer. For example, the first color conversion layer 230G may be formed with a first layer L1 and a second layer L2. The first layer L1 may be formed by inkjet-printing the first composition including the first quantum dot QD1 and curing the printed first composition. The second layer L2 may be formed by inkjet-printing the second composition including the second quantum dot QD2 on the first layer and curing the printed second composition. Accordingly, the first quantum dot QD1 and the second quantum dot QD2 of the first color conversion layer 230G may be separately provided in different layers. In an embodiment, thicknesses of the first layer L1 and the second layer L2 may vary according to contents of the first quantum dot QD1 and the second quantum dot QD2. For example, a thickness of the first layer L1 and a thickness of the second layer L2 may be different from each other. The thickness of the second layer L2 may be greater than the thickness of the first layer L1, but the disclosure is not necessarily limited thereto.

In an embodiment, the first composition may include a monomer, the first quantum dot QD1, a light scattering particle SCT, an initiator, a dispersant, and/or a viscosity control agent. The second composition may include a monomer, the second quantum dot QD2, a light scattering particle SCT, an initiator, a dispersant, and/or a viscosity control agent. A content of the first quantum dot QD1 of the first composition and a content of the second quantum dot QD2 may be different from each other. For example, the content of the second quantum dot QD2 may be greater than the content of the first quantum dot QD1, but the disclosure is not necessarily limited thereto.

A core of the first quantum dot QD1 may include a Group I-III-VI semiconductor compound. The Group I-III-VI semiconductor compound may include AgInS, AgInS₂, CuInS, CuInS₂, CuGaO₂, CuInGaS, AgGaO₂, AgInGaS, or a combination thereof. A shell of the first quantum dot QD1 may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or a combination thereof.

A core of the second quantum dot QD2 may include a Group III-V semiconductor compound. The Group III-V semiconductor compound may include InP, InAs, GaP, GaAs, GaN, AlP, AlAs, AlN, or a combination thereof. A shell of the second quantum dot QD2 may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or a combination thereof.

As described above, in case that the Group I-III-VI first quantum dot QD1 and the Group III-V second quantum dot QD2 are applied while being mixed together, efficiency may be improved and reflectivity may be decreased, compared to the case that a Group III-V quantum dot is independently applied. Material cost may be saved and wavelength conversion efficiency may be improved, compared to the embodiment that a Group I-III-VI quantum dot is independently applied, which has been described above.

Processes of forming a second color conversion layer 230R, a light scattering layer 230W, and the capping layer 270 have been described with reference to FIG. 6, and therefore, overlapping descriptions will be omitted.

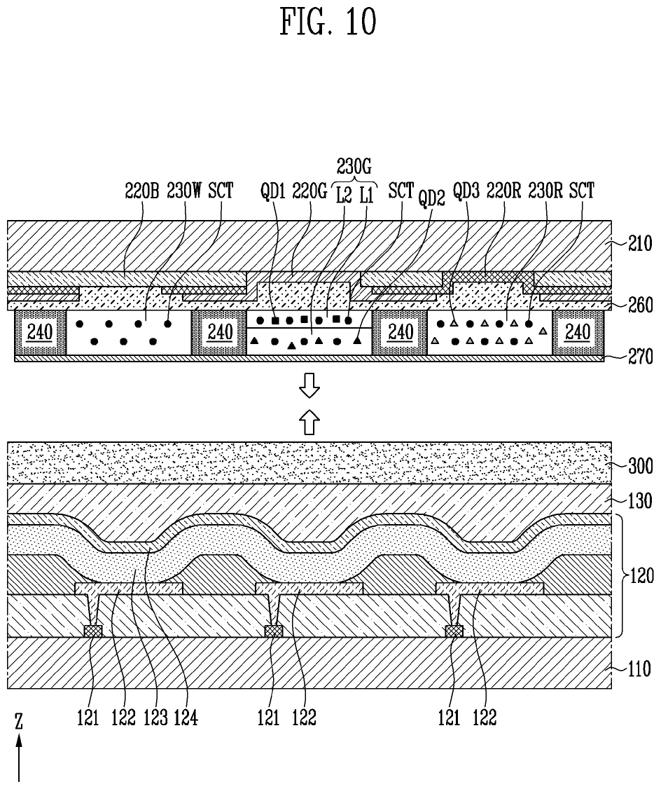

Referring to FIG. 10, subsequently, a first substrate 110 and the second substrate 210 may be bonded together, thereby completing the display device. A filling material 300 may be provided between the first substrate 110 and the second substrate 210.

In accordance with the disclosure, a Group I-III-VI quantum dot and a Group III-V quantum dot may be applied to a color conversion layer while being mixed together, so that efficiency may be improved and reflectivity may be decreased.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device, comprising:
a color conversion layer disposed above a light emitting element and including a first quantum dot and a second quantum dot, wherein
a core of the first quantum dot includes a Group I-III-VI semiconductor compound, and
a core of the second quantum dot includes a Group I-V semiconductor compound.

2. The display device of claim 1, wherein the Group I-III-VI semiconductor compound includes AgInS, AgInS₂, CuInS, CuInS₂, CuGaO₂, CuInGaS, AgGaO₂, AgInGaS, or a combination thereof.

3. The display device of claim 1, wherein the Group III-V semiconductor compound includes InP, InAs, GaP, GaAs, GaN, AlP, AlAs, AlN, or a combination thereof.

4. The display device of claim 1, wherein a content of the second quantum dot is greater than a content of the first quantum dot.

5. The display device of claim 1, wherein the color conversion layer includes a first layer and a second layer.

6. The display device of claim 5, wherein
the first layer includes the first quantum dot, and
the second layer includes the second quantum dot.

7. The display device of claim 6, wherein a thickness of the second layer is greater than a thickness of the first layer.

8. The display device of claim 1, wherein the color conversion layer further includes a light scattering particle.

9. The display device of claim 1, wherein the light emitting element includes a first electrode, a second electrode, and a light emitting layer between the first electrode and the second electrode.

10. The display device of claim 1, further comprising:
a color filter layer on the color conversion layer.

11. A display device comprising:
a first color conversion layer and a second color conversion layer, disposed above a light emitting element, wherein
the first color conversion layer includes a first quantum dot and a second quantum dot,
the second color conversion layer includes a third quantum dot,
a core of the first quantum dot includes a Group I-III-VI semiconductor compound, and
a core of the second quantum dot and a core of the third quantum dot include a Group III-V semiconductor compound.

12. The display device of claim 11, wherein the Group I-II-VI semiconductor compound includes AgInS, AgInS₂, CuInS, CuInS₂, CuGaO₂, CuInGaS, AgGaO₂, AgInGaS, or a combination thereof.

13. The display device of claim 11, wherein the Group III-V semiconductor compound includes InP, InAs, GaP, GaAs, GaN, AlP, AlAs, AlN, or a combination thereof.

14. The display device of claim 11, wherein a content of the second quantum dot is greater than a content of the first quantum dot.

15. The display device of claim 11, wherein the first color conversion layer includes a first layer and a second layer.

16. The display device of claim 15, wherein
the first layer includes the first quantum dot, and
the second layer includes the second quantum dot.

17. The display device of claim 16, wherein a thickness of the second layer is greater than a thickness of the first layer.

18. The display device of claim 16, wherein a thickness of the second color conversion layer is greater than a thickness of the second layer.

19. The display device of claim 11, wherein the first color conversion layer and the second color conversion layer further include a light scattering particle.

20. The display device of claim 11, wherein the light emitting element includes a first electrode, a second electrode, and a light emitting layer between the first electrode and the second electrode.
